(19) United States
(12) Patent Application Publication
(10) Pub. No.: US 2025/0155795 A1
(43) Pub. Date: May 15, 2025

(54) PHOTOMASK

(71) Applicant: Samsung Display Co., Ltd., Yongin-Si (KR)

(72) Inventor: HYUNG-GYU PARK, Yongin-si (KR)

(21) Appl. No.: 18/932,638

(22) Filed: Oct. 31, 2024

(30) Foreign Application Priority Data
Nov. 14, 2023 (KR) 10-2023-0157254

(51) Int. Cl. G03F 1/60; G03F 1/38; G03F 1/62

(52) U.S. Cl. CPC G03F 1/60; G03F 1/38; G03F 1/62

(57) ABSTRACT

A photomask includes: transparent substrate including a light-transmitting area and a light-blocking area adjacent to the light-transmitting area, and a light-blocking film disposed under the transparent substrate in the light-blocking area, wherein the transparent substrate has a recess that is at least partially in the light-transmitting area and adjacent to the light-blocking area.

### CROSS-REFERENCE TO RELATED APPLICATION(S)

This application claims priority to and benefit, under 35 U.S.C. § 119, of Korean Patent Application No. 10-2023-0157254 filed on Nov. 14, 2023 in the Korean Intellectual Property Office (KIPO), the entire contents of which are incorporated herein by reference.

### BACKGROUND

### 1. Technical Field

Embodiments relate to a photomask. More particularly, embodiments relate to a photomask used in a photolithography process.

### 2. Description of the Related Art

A semiconductor element or a display element may be manufactured through a photolithography process. The photolithography process involves determining a critical dimension of a semiconductor element or the like. The photolithography process may include a photoresist application process, an exposure process, and a development process. The exposure process is a process of transferring photomask patterns provided on a photomask substrate to a photoresist on a wafer.

### SUMMARY

Embodiments provide a photomask with improved quality.

A photomask according to an embodiment includes a transparent substrate including a light-transmitting area and a light-blocking area adjacent to the light-transmitting area and a light-blocking film disposed under the transparent substrate in the light-blocking area.

In an embodiment, the transparent substrate may have a recess that is at least partially in the light-transmitting area and adjacent to the light-blocking area.

In an embodiment, the recess may be adjacent to the light-blocking film.

In an embodiment, light passing through the transparent substrate may be refracted by a surface in the recess.

In an embodiment, the transparent substrate may include a lower surface in contact with the light-blocking film and an upper surface opposite to the lower surface, wherein the lower surface is approximately parallel to the upper surface.

In an embodiment, the recess may be a portion that is adjacent to the lower surface from which the transparent substrate is removed.

In an embodiment, the recess may include a first surface that is parallel to a plane at a border between the light-blocking area and the light-transmitting area and a second surface connecting the first surface of the and the lower surface.

In an embodiment, the first surface of the recess may be a flat surface.

In an embodiment, the first surface of the recess may be perpendicular to a surface of the light-blocking film that contacts the transparent substrate.

In an embodiment, the light-blocking film may include a side surface adjacent to the light-transmitting area.

In an embodiment, the first surface of the recess and the side surface of the light-blocking film may be disposed on the same plane.

In an embodiment, the second surface of the recess may be a flat surface that forms a non-right angle with respect to the first surface.

In an embodiment, the second surface of the recess may form an obtuse angle with the lower surface of the transparent substrate.

In an embodiment, the second surface of the recess may be a curved surface.

In an embodiment, the second surface of the recess may be a curved surface that curves around an imaginary center point that is located in the light-transmitting area of the transparent substrate.

In an embodiment, a thickness of the recess may be less than half of a thickness of the transparent substrate.

In an embodiment, a thickness of the recess may be greater than half of a thickness of the transparent substrate.

In an embodiment, the light-blocking film may include at least one of chromium (“Cr”), aluminum (“Al”), rubidium (“Ru”), tantalum (“Ta”), tantalum boron oxide (“TaBO”), and tantalum boron nitride (“TaBN”).

In an embodiment, the photomask may further include a pellicle disposed under the light-blocking film and protecting the light-blocking film.

In an embodiment, the recess may have a triangular shape in a cross-sectional view.

In an embodiment, the recess may have a shape of a right triangle in a cross-sectional view.

A photomask according to an embodiment includes a transparent substrate including a light-transmitting area and a light-blocking area adjacent to the light-transmitting area and a light-blocking film disposed under the transparent substrate in the light-blocking area.

In an embodiment, the transparent substrate may have a recess that is continuously formed in the light-transmitting area and the light-blocking area.

The photomask according to an embodiment may include a transparent substrate and a light-blocking film. The transparent substrate may include a light-transmitting area and a light-blocking area adjacent to the light-transmitting area. The light-blocking film may be disposed under the transparent substrate. In addition, the light-blocking film may overlap the light-blocking area. The transparent substrate may define a recess. The recess may partially overlap the light-transmitting area and be adjacent to the light-blocking area.

Accordingly, a phenomenon in which light passing through the transparent substrate is diffracted from vicinity of a side surface of the light-blocking film to the light-blocking area may be prevented. Thus, a phenomenon in which light reaches a target substrate in the light-blocking area may be prevented. Thus, a critical dimension of the semiconductor element or the display element may be reduced. Thus, the semiconductor element or the display element may include a pattern with a high resolution.

In addition, as the transparent substrate defines the recess, a phase shift mask for preventing diffraction of light may not be required. In addition, a lens including a hydrophobic polymer and preventing diffraction of light may not be required. Accordingly, manufacturing cost and manufacturing time of the photomask may be reduced.

### BRIEF DESCRIPTION OF THE DRAWINGS

Illustrative, non-limiting embodiments will be more clearly understood from the following detailed description in conjunction with the accompanying drawings.

FIG. 1 is a perspective view illustrating a photomask according to an embodiment and a target substrate.

FIG. 2 is a cross-sectional view illustrating an example of the photomask of FIG. 1 taken along a X-Y line.

FIG. 3 is a cross-sectional view illustrating light incident on the photomask of FIG. 2.

FIG. 4 is a cross-sectional view illustrating another example of the photomask of FIG. 1 taken along the X-Y line.

FIG. 5 is a cross-sectional view illustrating another example of the photomask of FIG. 1 taken along the X-Y line.

FIG. 6 is a cross-sectional view illustrating another example of the photomask of FIG. 1 taken along the X-Y line.

FIG. 7 is a cross-sectional view illustrating another example of the photomask of FIG. 1 taken along the X-Y line.

### DETAILED DESCRIPTION OF THE EMBODIMENTS

Hereinafter, display devices in accordance with embodiments will be described in more detail with reference to the accompanying drawings. The same reference numerals are used for the same components in the drawings, and redundant descriptions of the same components will be omitted.

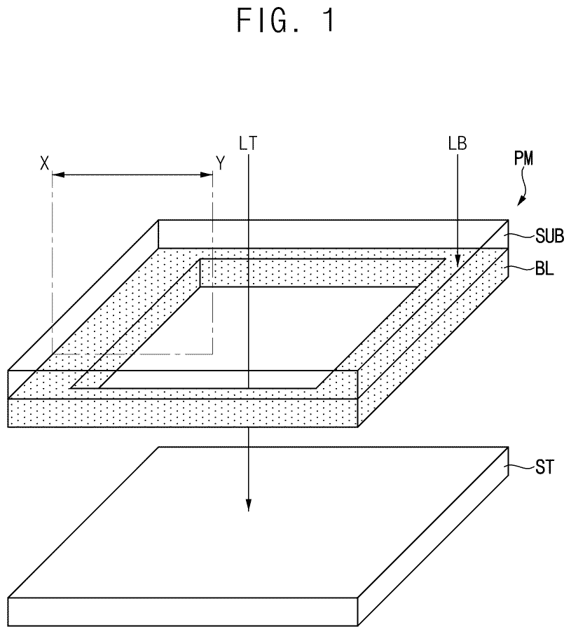

FIG. 1 is a perspective view illustrating a photomask according to an embodiment and a target substrate.

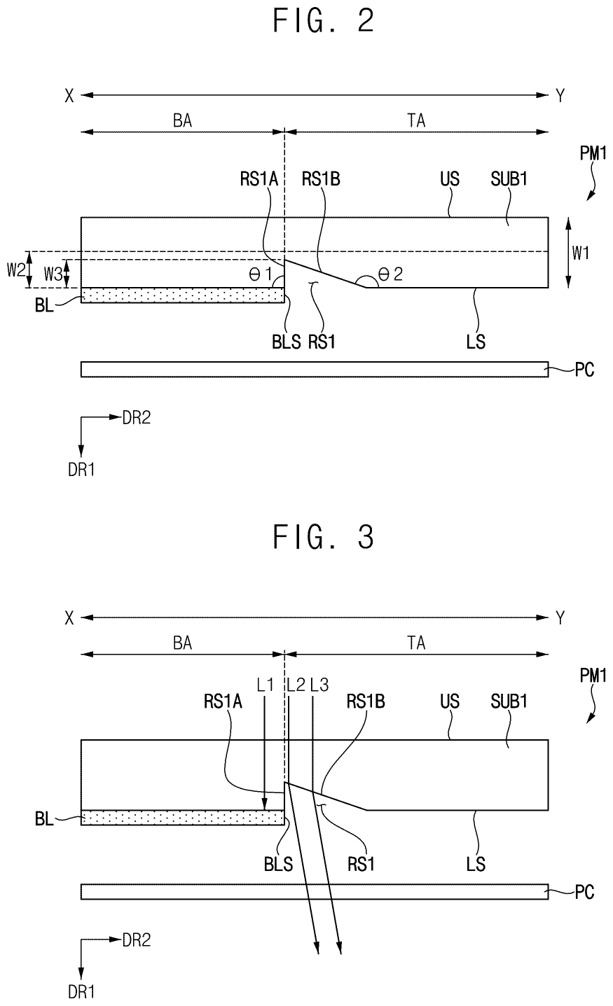

Referring to FIG. 1, a photomask PM according to an embodiment may include a transparent substrate SUB and a light-blocking film BL. The light-blocking film BL may overlap a light-blocking area (e.g., a light-blocking area BA of FIG. 2) in a plan view. As illustrated in FIG. 1, the light-blocking film BL may overlap less than all of the substrate SUB.

The photomask PM may be used in a photolithography process of a semiconductor element or a display element. In this case, a target substrate ST may include the semiconductor element or the display element. In addition, the target substrate ST may further include a photoresist disposed on the semiconductor element or the display element. For example, the target substrate ST may include a preliminary pixel defining layer and a photoresist disposed on the preliminary pixel defining layer.

Some light may not reach the target substrate ST in the light-blocking area, which has the light-blocking film BL. For example, a first light LB may be blocked by the light-blocking film BL and thus may not reach the target substrate ST.

Some light may reach the target substrate ST in a light-transmitting area (e.g., the light-transmitting area TA of FIG. 2). For example, a second light LT may pass through the transparent substrate SUB to reach the target substrate ST. The light-transmitting area TA may be adjacent to the light-blocking area BA, and the two areas may share a border as shown in FIG. 2.

FIG. 2 is a cross-sectional view illustrating an example of the photomask of FIG. 1 taken along an X-Y line. FIG. 3 is a cross-sectional view illustrating light incident on the photomask of FIG. 2.

Referring to FIG. 2, the first photomask PM1 may include a first transparent substrate SUB1, the light-blocking film BL, and a pellicle PC.

The first transparent substrate SUB1 may include an upper surface US and a lower surface LS that is approximately parallel to the upper surface. The lower surface LS of the first transparent substrate SUB1 may be in contact with the light-blocking film BL. For example, the lower surface LS of the first transparent substrate SUBI may be in contact with the light-blocking film BL in the light-blocking area BA.

The first transparent substrate SUB1 may include a transparent material. For example, the first transparent substrate SUB1 may include quartz.

The first transparent substrate SUB1 may have a first recess RS1. The first recess RS1 may be formed by removing a portion of the first transparent substrate SUB1 from the lower surface LS of the first transparent substrate SUB1. The first recess RS1 may partially overlap the light-transmitting area TA. In an embodiment, the first recess RS1 may be adjacent to the border between the light-blocking area BA and the light-transmitting area TA. In some embodiments, the first recess RS1 may be adjacent to the light-blocking film BL.

The first recess RS1 may include a first surface RS1A and a second surface RS1B. The first surface RS1A may be in or adjacent to the light-blocking area BA. The second surface RS1B may connect the first surface RS1A to the lower surface LS of the first transparent substrate SUB1.

In an embodiment, the first surface RS1A of the first recess RS1 may be a flat surface. In addition, an angle θ₁ formed between the first surface RS1A of the first recess RS1 and the light-blocking film BL may be about 90 degrees. That is, the first surface RS1A of the first recess RS1 may extend in a thickness direction (herein also referred to as a first direction DR1) of the first transparent substrate SUB1.

The light-blocking film BL may include a side surface BLS. The side surface BLS of the light blocking-film BL may coincide with or be adjacent to the border between the light-blocking area BA and the light-transmitting area TA. In an embodiment, the first surface RS1A of the first recess RS1 and the side surface BLS of the light-blocking film BL may be disposed on the same plane.

In an embodiment, the second surface RS1B of the first recess RS1 may be a flat surface. In addition, an angle θ₂ formed by the second surface RS1B of the first recess RS1 and the lower surface LS of the first transparent substrate SUB1 may be an obtuse angle.

In an embodiment, the first surface RS1A and the second surface RS1B of the first recess RS1 are neither parallel nor perpendicular to each other, the first recess RS1 may have a triangular shape in a cross-sectional view. For example, the first recess RS1 may have a right triangle shape in a cross-sectional view.

The first transparent substrate SUB1 may have a first thickness W1. For example, the first transparent substrate SUB1 may have the first thickness W1 in the first direction DR1. In addition, a second thickness W2 may be about half of the first thickness W1.

In an embodiment, a thickness W3, which is the length of the first surface RS1A of the first recess RS1 in the thickness direction DR1 may be less than a second thickness W2. For example, a thickness W3 of the first recess RS1 in the first direction DR1 may be less than the second thickness W2.

The light-blocking film BL may be disposed under the first transparent substrate SUB1. The light-blocking film BL may be positioned in the light-blocking area BA. In addition, the light-blocking layer BL may be adjacent to the light-transmitting area TA.

For example, the light-blocking film BL may include chromium (“Cr”), aluminum (“Al”), rubidium (“Ru”), tantalum (“Ta”), tantalum boron oxide (“TaBO”), tantalum boron nitride (“TaBN”), or the like. These materials may be used alone or in combination with each other.

The pellicle PC may be disposed under the light-blocking film BL. For example, the pellicle PC may be spaced apart from the light-blocking film BL in the first direction DR1. The pellicle PC may be formed of a light-transmitting material that transmits light. For example, the pellicle PC may have a light transmittance of 80% or more or 90% or more. The pellicle PC may protect the first photomask PM1. For example, the pellicle PC may protect the first photo mask PM1 from contaminants that may occur during the photolithography process. For example, the contaminant may include dust.

Referring to FIG. 3, some light may pass through the first transparent substrate SUB1 in the light-transmitting area TA. For example, each of a second light L2 and a third light L3 may pass through the first transparent substrate SUB1 to reach the target substrate (for example, the target substrate ST of FIG. 1).

Each of the second light L2 and the third light L3 may be incident on the first transparent substrate SUB1. That is, each of the second light L2 and the third light L3 may be incident on the first transparent substrate SUB1 in the first direction DR1.

Some light may be blocked by the light-blocking film BL in the light-blocking area BA. For example, the first light L1 may be blocked by the light-blocking film BL in the light-blocking area BA, as depicted in FIG. 3. Accordingly, the first light L1 may not reach the target substrate.

The first transparent substrate SUB1 may have a refractive index different from a refractive index of air around the first transparent substrate SUB1. For example, the first transparent substrate SUB1 may have the refractive index greater than the refractive index of air. Accordingly, each of the second light L2 and the third light L3 may be refracted by the second surface RS1B of the first recess RS1. For example, each of the second light L2 and the third light L3 may be refracted in a direction away from the light-blocking area BA.

That is, as the first transparent substrate SUB1 defines the first recess RS1, a phenomenon in which light passing through the first transparent substrate SUB1 is diffracted from the vicinity of the side surface BLS of the light-blocking film BL to the light-blocking area BA may be prevented. Therefore, a phenomenon in which the light reaches the target substrate in the light-blocking area BA may be prevented.

Accordingly, a critical dimension of the semiconductor element or the display element may be reduced. This allows the semiconductor element or the display element to include a pattern with a high resolution.

In addition, as the first transparent substrate SUB1 defines the first recess RS1, a phase shift mask for preventing diffraction of lights may not be required. Therefore, manufacturing cost and manufacturing time of the first photomask PM1 may be reduced.

In addition, as the first transparent substrate SUB1 defines the first recess RS1, a lens including a hydrophobic polymer and preventing diffraction of light may not be required. Therefore, the manufacturing cost and manufacturing time of the first photomask PM1 may be reduced.

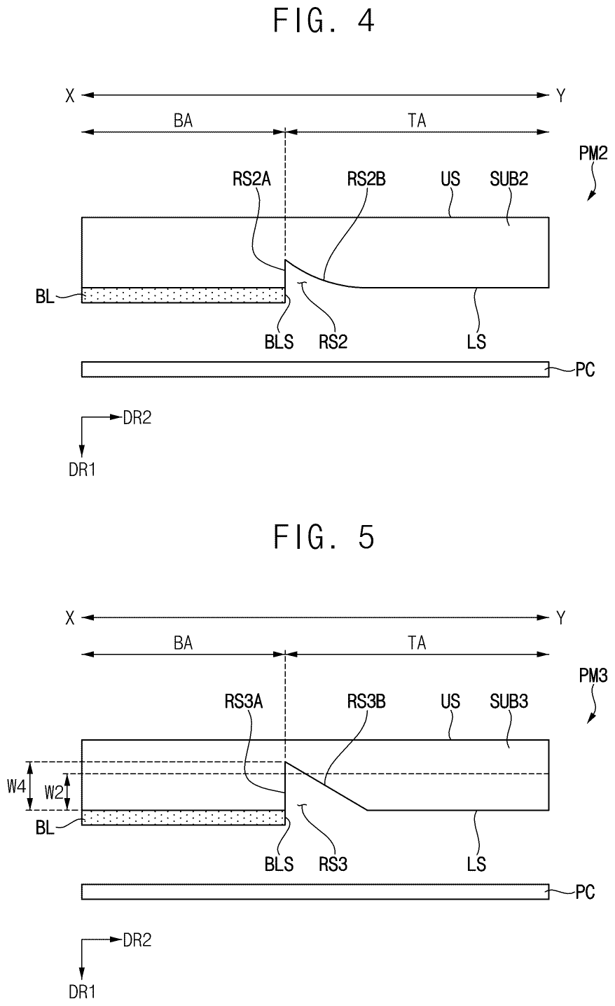

FIG. 4 is a cross-sectional view illustrating another example of the photomask of FIG. 1 taken along the X-Y line.

A second photomask PM2 described with reference to FIG. 4 may be substantially the same as or similar to the first photomask PM1 described with reference to FIG. 2 except for a shape of a second recess RS2. Accordingly, redundant descriptions will be omitted or simplified.

Referring to FIG. 4, the second photomask PM2 may include a second transparent substrate SUB2, the light-blocking film BL, and the pellicle PC.

The second transparent substrate SUB2 may define a second recess RS2. The second recess RS2 may include a first surface RS2A and a second surface RS2B. The first surface RS2A of the second recess RS2 may be adjacent to the light-blocking area BA. The second surface RS2B of the second recess RS2 may connect the first surface RS2A of the second recess RS2 to a lower surface LS of the second transparent substrate SUB2.

In an embodiment, the first surface RS2A of the second recess RS2 may be a flat surface. In addition, the first surface RS2A of the second recess RS2 may be parallel to a plane defined by the thickness direction DR1 of the second transparent substrate SUB2 and a third direction (not shown) that is perpendicular to the first direction DR1 and the second direction DR2. That is, the first surface RS2A may extend in the first direction DR1.

The light-blocking film BL may include a side surface BLS. The side surface BLS may be adjacent to the light-transmitting area TA. In an embodiment, the first surface RS2A of the second recess RS2 and the side surface BLS of the light-blocking film BL may be disposed on the same plane.

In an embodiment, the second surface RS2B of the second recess RS2 may be a curved surface. For example, the second surface RS2B of the second recess RS2 may form a curved surface that curves around an imaginary center point that is in the light-transmitting area of the transparent substrate.

FIG. 5 is a cross-sectional view illustrating another example of the photomask of FIG. 1 taken along the X-Y line.

A third photomask PM3 described in reference to FIG. 5 may be substantially the same as or similar to the first photomask PM1 described with reference to FIG. 2 except for a shape of a third recess RS3. Accordingly, redundant descriptions will be omitted or simplified.

Referring to FIG. 5, the third photomask PM3 may include a third transparent substrate SUB3, the light-blocking film BL, and the pellicle PC.

The third transparent substrate SUB3 may define a third recess RS3. The third recess RS3 may include a first surface RS3A and a second surface RS3B. The first surface RS3A of the third recess RS3 may be adjacent to the light-blocking area BA. The second surface RS3B of the third recess RS3 may connect the first surface RS3A of the third recess RS3 to a lower surface LS of the third transparent substrate SUB3.

In an embodiment, the first surface RS3A of the third recess RS3 may be a flat surface. In addition, the first surface RS3A of the third recess RS3 may be parallel to a plane formed by a thickness direction DR1 of the third transparent substrate SUB3 and a third direction (not shown) that is perpendicular to the first direction DR1 and the second direction DR2. That is, the first surface RS3A of the third recess RS3 may extend in the first direction DR1.

The light-blocking layer BL may include a side surface BLS. The side surface BLS may be adjacent to the light-transmitting area TA. In an embodiment, the first surface RS3A of the third recess RS3 and the side surface BLS of the light-blocking film BL may be flush, disposed on the same plane.

In an embodiment, the second surface RS3B of the third recess RS3 may be a flat surface.

The third transparent substrate SUB3 may have a first thickness W1. Specifically, the third transparent substrate SUB3 may have the first thickness W1 in the first direction DR1. In addition, a second thickness W2 having a size of half of the first thickness W1 may be defined.

In an embodiment, a thickness W4 of the third recess RS3 may be greater than the second thickness W2. Specifically, the thickness W4 of the third recess RS3 in the first direction DR1 may be greater than the second thickness W2.

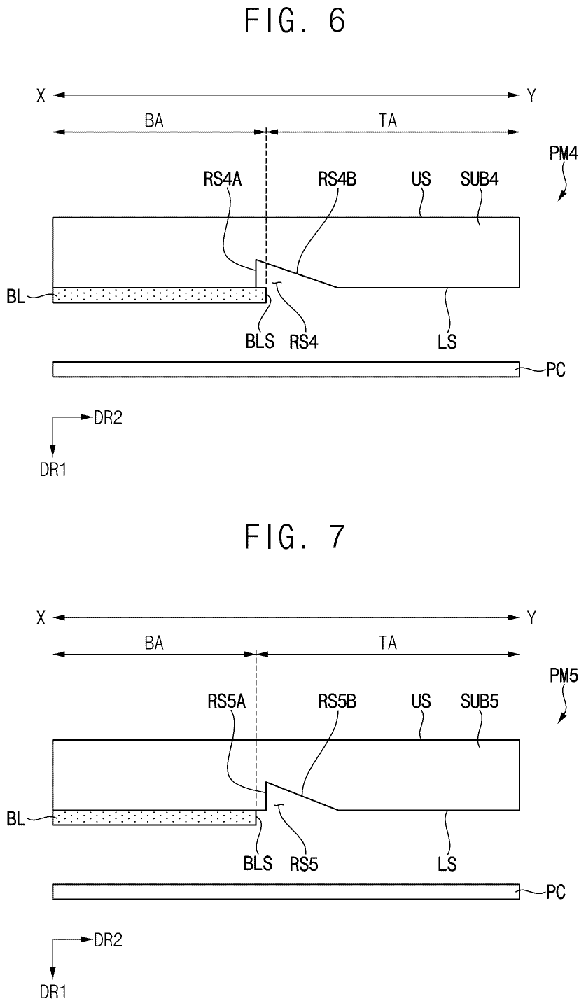

FIG. 6 is a cross-sectional view illustrating another example of the photomask of FIG. 1 taken along the X-Y line.

The fourth photomask PM4 described with reference to FIG. 6 may be substantially the same as or similar to the first photomask PMI described with reference to FIG. 2 except for a shape of a fourth recess RS4. Thus, redundant descriptions will be omitted or simplified.

Referring to FIG. 6, the fourth photomask PM4 may include a fourth transparent substrate SUB4, the light-blocking layer BL, and the pellicle PC.

The fourth transparent substrate SUB4 may define the fourth recess RS4. The fourth recess RS4 may include a first surface RS4A and a second surface RS4B. The first surface RS4A of the fourth recess RS4 may be adjacent to the light-blocking area BA. The second surface RS4B of the fourth recess RS4 may connect the portion of the first surface RS4A of the fourth recess RS4 that is closest to the upper surface US of the fourth transparent substrate SUB4 to a lower surface LS of the fourth transparent substrate SUB4.

In an embodiment, the first surface RS4A of the fourth recess RS4 may be a flat surface. In addition, the first surface RS4A of the fourth recess RS4 may be parallel to a plane that is defined by the first direction DR1 and the third direction (not shown), the third direction being perpendicular to both the first direction DR1 and the second direction DR2. The first surface RS4A of the fourth recess RS4 may extend in the first direction DR1.

The light-blocking film BL may include a side surface BLS. The side surface BLS may be adjacent to the light-transmitting area TA. In an embodiment, the first surface RS4A of the fourth recess RS4 and the side surface BLS of the light-blocking film BL may be disposed on parallel but different planes. For example, the first surface RS4A of the fourth recess RS4 may be squarely in the light-blocking area BA. In this case, the fourth recess RS4 may partially extend into the light-blocking area BA.

In an embodiment, the second surface RS4B of the fourth recess RS4 may be a flat surface positioned at a non-right angle with respect to the first surface RS4A of the fourth recess RS4.

FIG. 7 is a cross-sectional view illustrating another example of the photomask of FIG. 1 taken along the X-Y line.

The fifth photomask PM5 described with reference to FIG. 7 may be substantially the same as or similar to the first photo mask PM1 described with reference to FIG. 2 except for a shape of a fifth recess RS5. Thus, redundant descriptions are omitted or simplified.

Referring to FIG. 7, the fifth photomask PM5 may include a fifth transparent substrate SUB5, the light-blocking film BL, and the pellicle PC.

The fifth transparent substrate SUB5 may define a fifth recess RS5. The fifth recess RS5 may include a first surface RS5A and a second surface RS5B. The first surface RS5A of the fifth recess RS5 may be in the light transmitting area TA adjacent to the light-blocking area BA. The second surface RS5B of the fifth recess RS5 may connect the first surface RS5A of the fifth recess RS5 to a lower surface LS of the fifth transparent substrate SUB5.

In an embodiment, the first surface RS5A of the fifth recess RS5 may be a flat surface. In addition, the first surface RS5A of the fifth recess RS5 may be parallel to a plane that is formed by the first direction DR1 and the third direction (not shown) that is perpendicular to both the first direction DR1 and the second direction DR2, and extend in a thickness direction DR1 of the fifth transparent substrate SUB5. That is, the first surface RS5A may extend in the first direction DR1.

The light-blocking layer BL may include a side surface BLS. The side surface BLS of the light-blocking layer BL may be adjacent to the light-transmitting area TA, or coincide with the border between the light-blocking area BA and the light-transmitting area TA. In an embodiment, the first surface RS5A of the fifth recess RS5 and the side surface BLS of the light-blocking film BL may be disposed on parallel but different planes. For example, the first surface RS5A of the fifth recess RS5 may be squarely in the light-transmitting area TA. In this case, the fifth recess RS5 may be in the light-transmitting area TA. In addition, the fifth recess RS5 may be outside the light-blocking area BA.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting to the disclosure. Although a few embodiments have been described, those skilled in the art will readily appreciate that many modifications are possible in the embodiments without materially departing from the novel teachings and advantages of the present inventive concept.

Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A photomask comprising:
a transparent substrate including a light-transmitting area and a light-blocking area adjacent to the light-transmitting area; and
a light-blocking film disposed under the transparent substrate in the light-blocking area,
wherein the transparent substrate has a recess that is at least partially in the light-transmitting area and adjacent to the light-blocking area.

2. The photomask of claim 1, wherein the recess is adjacent to the light-blocking film.

3. The photomask of claim 1, wherein light passing through the transparent substrate is refracted by a surface of the recess.

4. The photomask of claim 1, wherein the transparent substrate includes a lower surface in contact with the light-blocking film and an upper surface opposite to the lower surface, wherein the lower surface is approximately parallel to the upper surface, and
the recess is a portion adjacent to the lower surface from which the transparent substrate is removed.

5. The photomask of claim 4, wherein the recess includes a first surface that is parallel to a plane at a border between the light-blocking area and the light-transmitting area and a second surface connecting the first surface and the lower surface.

6. The photomask of claim 5, wherein the first surface of the recess is a flat surface.

7. The photomask of claim 6, wherein the first surface of the recess is perpendicular to a surface of the light-blocking film that contacts the transparent substrate.

8. The photomask of claim 7, wherein the light-blocking film includes a side surface adjacent to the light-transmitting area, and the first surface of the recess and the side surface of the light-blocking film are disposed on the same plane.

9. The photomask of claim 5, wherein the second surface of the recess is a flat surface that forms a non-right angle with respect to the first surface.

10. The photomask of claim 9, wherein the second surface of the recess forms an obtuse angle with the lower surface of the transparent substrate.

11. The photomask of claim 5, wherein the second surface of the recess is a curved surface.

12. The photomask of claim 11, wherein the second surface of the recess is a curved surface that curves around an imaginary center point that is located in the light-transmitting area of the transparent substrate.

13. The photomask of claim 1, wherein a thickness of the recess is less than half of a thickness of the transparent substrate.

14. The photomask of claim 1, wherein a thickness of the recess is greater than half of a thickness of the transparent substrate.

15. The photomask of claim 1, wherein the light-blocking film includes at least one of chromium (“Cr”), aluminum (“Al”), rubidium (“Ru”), tantalum (“Ta”), tantalum boron oxide (“TaBO”), and tantalum boron nitride (“TaBN”).

16. The photomask of claim 1, further comprising:
a pellicle disposed under the light-blocking film and protecting the light-blocking film.

17. The photomask of claim 1, wherein the recess has a triangular shape in a cross-sectional view.

18. The photomask of claim 17, wherein the recess has a shape of a right triangle in a cross-sectional view.

19. A photomask comprising:
a transparent substrate including a light-transmitting area and a light-blocking area adjacent to the light-transmitting area; and
a light-blocking film disposed under the transparent substrate in the light-blocking area,
wherein the transparent substrate has a recess continuously formed in the light-transmitting area and the light-blocking area.
